(19) United States
(12) Patent Application Publication
(10) Pub. No.: US 2026/0221943 A1
(43) Pub. Date: Jul. 30, 2026

(54) AMPLIFIER

(71) Applicant: Fujitsu Limited, Kawasaki-shi (JP)

(72) Inventor: Masaru SATO, Isehara (JP)

(73) Assignee: Fujitsu Limited, Kawasaki-shi (JP)

(21) Appl. No.: 19/440,717

(22) Filed: Jan. 6, 2026

(30) Foreign Application Priority Data
Jan. 30, 2025 (JP) 2025-013520

(51) Int. Cl. H03F 1/02; H03F 3/60

(52) U.S. Cl. CPC H03F 1/0288; H03F 3/602; H03F 2200/204; H03F 2200/255; H03F 2200/543

(57) ABSTRACT

An amplifier includes a rat-race coupler, a first peak amplifier configured to perform class C amplification, a second peak amplifier configured to perform class C amplification with a phase inverted relative to the first peak amplifier, a carrier amplifier configured to perform AB class amplification, a 180-degree hybrid circuit configured to invert a phase of either a signal transmitted from a third terminal to a second terminal or a signal transmitted from a fourth terminal to the second terminal and to output signals from the second terminal in phase with each other, a first transmission line having a quarter wavelength and coupled between a fourth port of the rat-race coupler and the first peak amplifier, and a transmission line having the quarter wavelength and coupled between the first peak amplifier and a terminal of the carrier amplifier.

### CROSS-REFERENCE TO RELATED APPLICATIONS

This application is based upon and claims priority to Japanese Patent Application No. 2025-013520, filed on January 30, 2025, the entire contents of which are incorporated herein by reference.

### FIELD

The embodiments discussed herein are related to amplifiers.

### BACKGROUND

A conventional integrated Doherty amplifier includes a) a main amplifier stage that receives a first signal and amplifies the first signal to generate a first amplified signal, b) at least one peak amplifier stage that receives each of at least one second signal and starts operation when a level of each second signal reaches a predetermined threshold, c) at least one lumped-element hybrid power distributor that distributes an input signal of the amplifier to the first signal and the at least one second signal with a predetermined phase shift and an unequal distribution ratio, and d) at least one lumped-element pseudo line that receives the first amplified signal and applies the predetermined phase shift to the first amplified signal, as described in Japanese National Publication of International Patent Application No. 2008/541648, for example.

In the conventional integrated Doherty amplifier, when the main amplifier stage amplifies the signal, the peak amplifier stage is not disconnected from the main amplifier stage, and the signal is supplied to the peak amplifier stage. As a result, power added efficiency may be reduced. In addition, when the peak amplifier stage amplifies the signal, the main amplifier stage is not disconnected from the peak amplifier stage, and thus the power added efficiency may be reduced.

### SUMMARY

According to one aspect of the embodiments, it is an object in one aspect of the embodiments to provide an amplifier that suppresses reductions in power added efficiency.

According to one aspect of the embodiments, an amplifier includes a rat-race coupler including a first port, a second port, a third port, and a fourth port to which an input signal is to be input. The rat-race coupler includes a plurality of quarter-wavelength transmission lines at a frequency of the input signal, the plurality of quarter-wavelength transmission lines being respectively coupled between the first port and the second port, between the second port and the third port, and between the third port and the fourth port. The rat-race coupler includes a three-quarter wavelength transmission line at the frequency of the input signal, the three-quarter wavelength transmission line being coupled between the first port and the fourth port. The amplifier includes a first peak amplifier coupled to the fourth port and configured to perform class C amplification, a second peak amplifier coupled to the second port and configured to perform class C amplification with a phase inverted relative to the first peak amplifier, a carrier amplifier coupled to the third port and configured to perform AB class amplification, and a 180-degree hybrid circuit including a first terminal coupled to an output terminal of the carrier amplifier, a second terminal, a third terminal coupled to an output terminal of the first peak amplifier, and a fourth terminal coupled to an output terminal of the second peak amplifier, the 180-degree hybrid circuit being configured to invert a phase of either a signal transmitted from the third terminal to the second terminal or a signal transmitted from the fourth terminal to the second terminal, and output signals from the second terminal in phase with each other. The amplifier includes a first transmission line having a quarter wavelength length and coupled between the fourth port and the first peak amplifier, and a second transmission line having the quarter wavelength length coupled between the first peak amplifier and the third terminal of the carrier amplifier.

The object and advantages of the invention will be realized and attained by means of the elements and combinations particularly pointed out in the claims.

It is to be understood that both the foregoing general description and the following detailed description are exemplary and explanatory and are not restrictive of the invention, as claimed.

### BRIEF DESCRIPTION OF DRAWINGS

FIG. 1 is a diagram illustrating a configuration example of an amplifier 100 according to an embodiment;

FIG. 2 is a diagram illustrating an example of an operating state of the amplifier 100 at average power;

FIG. 3A is a diagram illustrating an example of an S31 parameter of power passing from a port 1A to a port 3A of a rat-race coupler 110 in the operating state of the amplifier 100 at the average power;

FIG. 3B is a diagram illustrating an example of an S21 parameter of power passing from a port 1B to a port 2B of a 180-degree hybrid circuit 140 in the operating state of the amplifier 100 at the average power;

FIG. 4 is a diagram illustrating an example of the operating state of the amplifier 100 at maximum power;

FIG. 5A is a diagram illustrating an example of the S21 parameter of the power passing from the port 1A to the port 2A, the S31 parameter of the power passing from the port 1A to the port 3A, and an S41 parameter of power passing from the port 1A to a port 4A of the rat-race coupler 110, in the operating state of the amplifier 100 at the maximum power;

FIG. 5B is a diagram illustrating an example of S parameters of power passing from ports 3B and 4B to the port 2B of the 180-degree hybrid circuit 140 in the operating state of the amplifier 100 at the average power; and

FIG. 6 is a diagram illustrating an example of the relationship between output power (W) and power added efficiency (%) of the amplifier 100.

### DESCRIPTION OF EMBODIMENTS

Hereinafter, embodiments to which an amplifier of the present disclosure is applied will be described.

### Embodiments

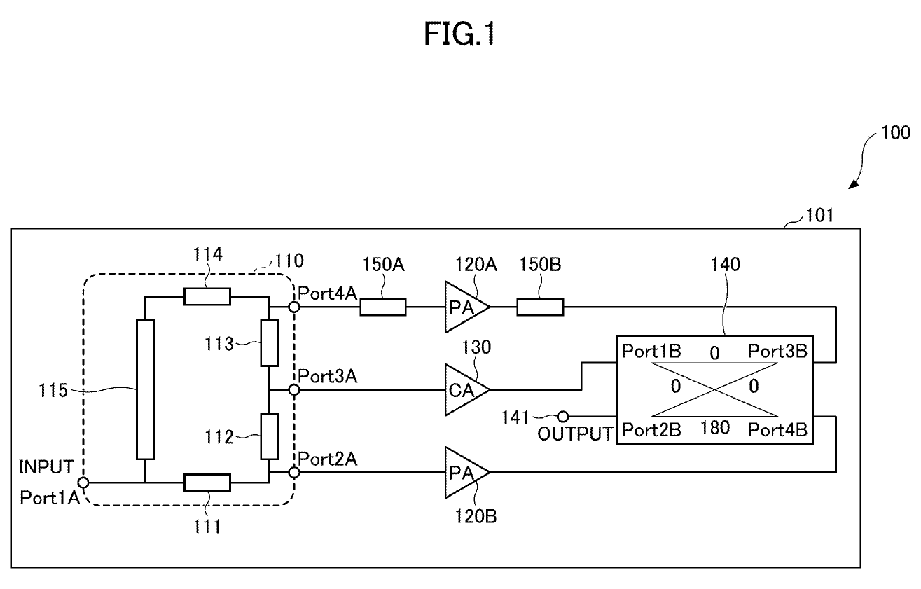

FIG. 1 is a diagram illustrating a configuration example of an amplifier 100 according to an embodiment. For example, the amplifier 100 is an amplifier that can be mounted on a radio unit (RU) of a front end of a base station, as an example, and can be used as a power amplifier coupled upstream of an antenna.

An input signal of the amplifier 100 is, for example, a transmission signal of a millimeter wave band such as a fifth generation mobile communication system (5G), or a frequency band of 1 GHz to 30 GHz including Sub-6.

### Configuration of Amplifier 100

The amplifier 100 includes a substrate 101, a rat-race coupler 110, peak amplifiers (PAs) 120A and 120B, a carrier amplifier (CA) 130, a 180-degree hybrid circuit 140, and transmission lines 150A and 150B.

The PA 120A is an example of a first peak amplifier, and the PA 120B is an example of a second peak amplifier. The transmission line 150A is an example of a first transmission line, and the transmission line 150B is an example of a second transmission line.

### Substrate 101

The substrate 101 is housed in a package of the amplifier 100, and is, as an example, a multilayer wiring substrate of FR-4 (Flame Retardant type 4) standard. The rat-race coupler 110, the PAs 120A and 120B, the CA 130, the 180-degree hybrid circuit 140, and the transmission lines 150A and 150B are mounted on the substrate 101.

In FIG. 1, transmission lines 111, 112, 113, 114, and 115 and the transmission lines 150A and 150B of the rat-race coupler 110 are part of transmission lines (wirings) on the substrate 101, and each of these transmission lines has a predetermined length corresponding to an electric length of a wavelength at the frequency of an input signal that is amplified by the amplifier 100. In addition to the transmission lines 111 to 115 and transmission lines 150A and 150B, the amplifier 100 has transmission lines (wirings) that couple components. However, lengths of these transmission lines (wirings) are negligible compared with the lengths of the transmission lines 111 to 115 and the transmission lines 150A and 150B of the rat-race coupler 110, and thus the description of the transmission lines (wirings) is omitted.

The characteristic impedance of each of the transmission lines (wirings) of the substrate 101, other than the transmission lines 111 to 115 and the transmission lines 150A and 150B, is, for example, 50 Ω. The characteristic impedance of each of the transmission lines 150A and 150B is, for example, 50 Ω.

In the following, the input signal that the amplifier 100 amplifies may be simply referred to as an input signal. The input signal is an input signal that is input to a port 1A, which is an input terminal of the rat-race coupler 110, and that is amplified by the amplifier 100.

### Rat-race Coupler 110

The rat-race coupler 110 has the transmission lines 111 to 115 and ports 1A, 2A, 3A, and 4A. The transmission lines 111 to 115 are coupled in this order in a loop from the port 1A to the port 1A via ports 2A, 3A, and 4A. The port 1A is coupled between transmission lines 115 and 111, the port 2A is coupled between transmission lines 111 and 112, the port 3A is coupled between transmission lines 112 and 113, and the port 4A is coupled between transmission lines 113 and 114.

The port 1A is coupled to an output terminal of a transmission circuit that outputs the input signal. The port 2A is coupled to an input terminal of the PA 120B. The port 3A is coupled to an input terminal of the CA 130. The port 4A is coupled to an input terminal of the PA 120A via the transmission line 150A.

Each of the transmission lines 111 to 114 has a length of a quarter wavelength at the frequency of the input signal. The transmission lines 111 to 114 are formed on the substrate 101, and the quarter wavelength at the frequency of the input signal is, more specifically, a length corresponding a quarter of an electrical length in consideration of a dielectric constant of the substrate 101. That is, the length of each of the transmission lines 111 to 114 is a quarter of the electrical length of the wavelength at the frequency of the input signal.

The transmission line 115 has a length of a half wavelength at the frequency of the input signal. The transmission line 115 is formed on the substrate 101, and the half wavelength at the frequency of the input signal is, more specifically, a half of an electrical length in consideration of the dielectric constant of the substrate 101. That is, the length of the transmission line 115 is the half of the electrical length of the wavelength at the frequency of the input signal.

A transmission line combining transmission lines 114 and 115 has a length of a three-quarter wavelength at the frequency of the input signal. The transmission lines 114 and 115 are formed on the substrate 101, and the three-quarter wavelength at the frequency of the input signal is, more specifically, three quarters of the electrical length in consideration of the dielectric constant of the substrate 101. That is, the length of the transmission line combining the transmission lines 114 and 115 is three quarters of the electrical length of the wavelength at the frequency of the input signal.

Although the transmission lines 114 and 115 are illustrated separately in this description, the transmission lines 114 and 115 may be integrated. Instead of the transmission lines 114 and 115, one transmission line having a length of the three-quarter wavelength at the frequency of the input signal may be used.

The rat-race coupler 110 distributes the input signal that is input to the port 1A, to the ports 2A, 3A, and 4A, and outputs the resulting signals.

### PA 120A

The PA 120A has the input terminal coupled to the port 4A via the transmission line 150A, and an output terminal coupled to the port 3B of the 180-degree hybrid circuit 140 via the transmission line 150B. The PA 120A is an amplifier that performs class-C amplification, amplifies the input signal that is input via the transmission line 150A, and outputs the amplified signal to the transmission line 150B. The PA 120A may be a GaN-high electron mobility transistor (HEMT), an HEMT made of a material other than GaN, or an amplifier made of a semiconductor other than the above HEMTs. The same applies to the PA 120B and the CA 130.

### PA 120B

The PA 120B has the input terminal coupled to the port 2A, and an output terminal coupled to the port 4B of the 180-degree hybrid circuit 140. The PA 120B is an amplifier that performs class C inverting amplification. The PA 120B invertingly amplifies the input signal that is input from the port 2A, and outputs the resulting signal to the port 4B of the 180-degree hybrid circuit. The PA 120B has the same size as the PA 120A. Having the same amplifier size means, for example, that gate widths of the PA 120A and the PA 120B are equal and the amplification factors are the same.

In this example, a configuration in which the PA 120B invertingly amplifies the input signal and the PA 120A amplifies the input signal without changing the phase of the input phase will be described. It is sufficient that one of the PA 120A and the PA 120B performs inverting amplification so that the output phases differ by 180 degrees. In this case, the PA 120A may invertingly amplify the input signal, and the PA 120B may amplify the input signal without changing the phase of the input signal. It is sufficient that the PA 120B is an amplifier that performs class C amplification with a phase inverted with respect to the PA 120A.

### CA 130

The CA 130 is an amplifier having the input terminal coupled to the port 3A and an output terminal coupled to the port 1B of the 180-degree hybrid circuit 140. The CA 130 performs AB class amplification.

### 180-Dgree Hybrid Circuit 140

The 180-degree hybrid circuit 140 is a four-terminal circuit having ports 1B, 2B, 3B, and 4B. The port 1B is coupled to the output terminal of the CA 130, the port 2B is used as an output terminal, the port 3B is coupled to the output terminal of the PA 120A via the transmission line 150B, and the port 4B is coupled to the output terminal of the PA 120B. An output terminal 141 is coupled to the port 2B. The output terminal 141 is an output terminal of the amplifier 100, and when the amplifier 100 is used as an amplifier of the radio unit (RU) at the front end of the base station, the antenna of the base station is coupled to the output terminal 141.

The 180-degree hybrid circuit 140 does not change the phase of the signal input to the port 1B, and transmits the signal to the ports 3B and 4B in a state where a phase shift is 0 degrees. The phase shift is an amount by which the phase changes, and an amount by which the phase is delayed with respect to the signal before the phase change.

The 180-degree hybrid circuit 140 transmits the signal input to the port 3B to the ports 1B and 2B in a state where the phase shift is 0 degrees, without changing the signal phase.

The 180-degree hybrid circuit 140 transmits the signal input to the port 4B to the port 1B in a state where the phase shift is 0 degrees, without changing the signal phase. Also, after changing the signal phase by 180 degrees, the 180-degree hybrid circuit 140 transmits the signal input to the port 4B to the port 2B in a state where the phase shift is 180 degrees.

### Transmission Lines 150A and 150B

The transmission line 150A is a transmission line coupling the port 4A and the input terminal of the PA 120A. The transmission line 150B is a transmission line coupling the output terminal of the PA 120A and the port 3B of the 180-degree hybrid circuit 140.

Each of the transmission lines 150A and 150B has a length of a quarter wavelength at the frequency of the input signal. The transmission lines 150A and 150B are formed on the substrate 101, and the quarter wavelength at the frequency of the input signal is, more specifically, a quarter of the electrical length in consideration of the dielectric constant of the substrate 101. That is, the length of each of the transmission lines 150A and 150B is the quarter of the electrical length of the wavelength at the frequency of the input signal.

The characteristic impedance of each of the transmission lines 150A and 150B is, for example, 50 Ω.

### Operations at Average Power and Maximum Power of Amplifier 100

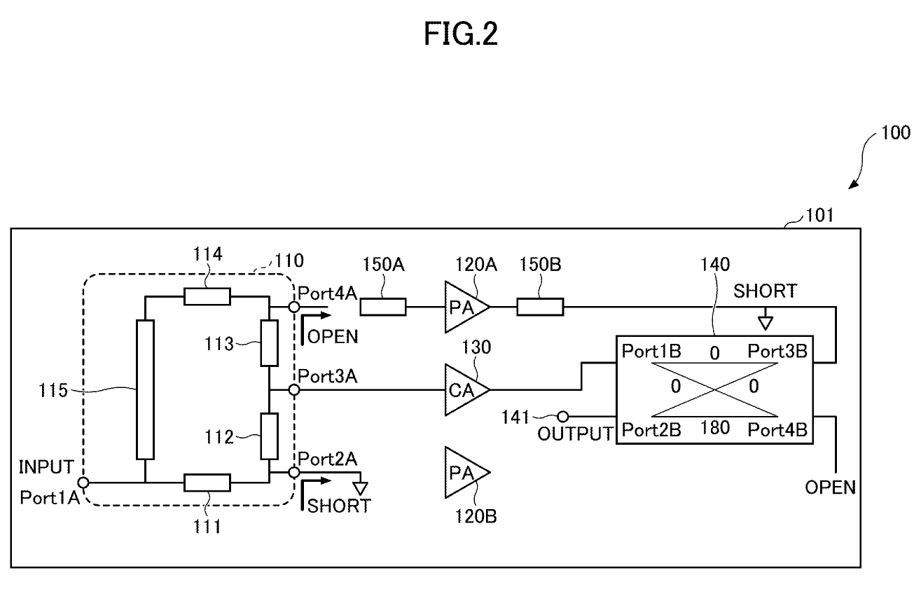

Next, an example of operations at average power and maximum power of the amplifier 100 will be described with reference to FIGS. 2, 3A, 3B, 4, 5A, and 5B.

The operation of the amplifier 100 at average power is an operation of the amplifier 100 when a power level of the input signal input to the port 1A of the rat-race coupler 110 is, for example, one-tenth of saturation power of each of the PA 120A and the PA 120B. One-tenth of the saturation power of each of the PA 120A and the PA 120B is an example of a first level that is at a predetermined percentage of the saturation power of each of the PA 120A and the PA 120B. The average power is not limited to one-tenth of the saturation power, and may be power about 6dB to 9dB lower than the saturation power.

The operation of the amplifier 100 at the maximum power means that the amplifier 100 operates when a power level of the input signal input to the port 1A of the rat-race coupler 110 is a saturation power level of each of the PA 120A and the PA 120B.

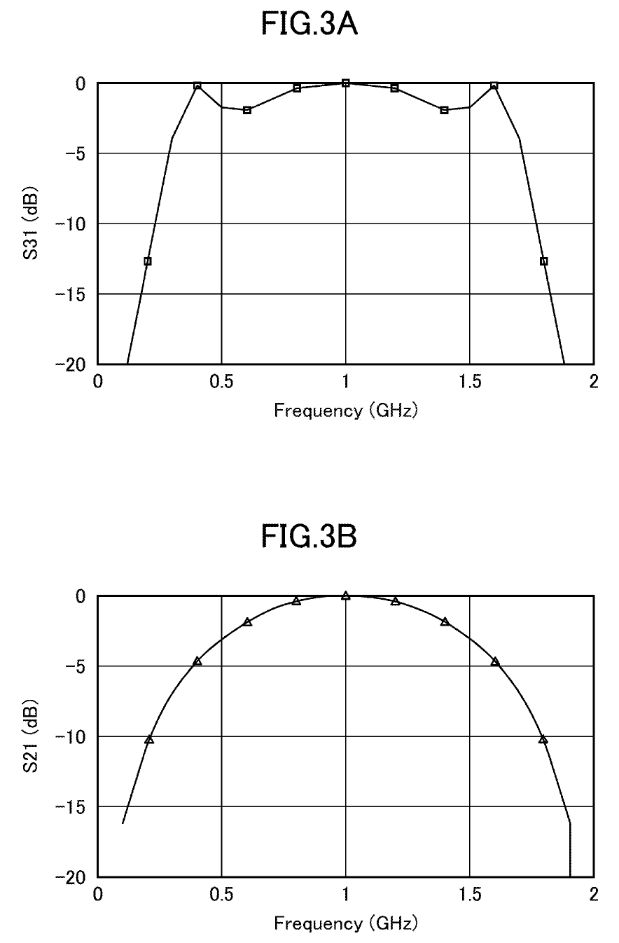

FIG. 2 is a diagram illustrating an example of an operating state of the amplifier 100 at the average power. FIG. 3A is a diagram illustrating an example of an S31 parameter of power passing from the port 1A to the port 3A of the rat-race coupler 110 in the operating state of the amplifier 100 at the average power. FIG. 3B is a diagram illustrating an example of an S21 parameter of power passing from the port 1B to the port 2B of the 180-degree hybrid circuit 140 in the operating state of the amplifier 100 at the average power.

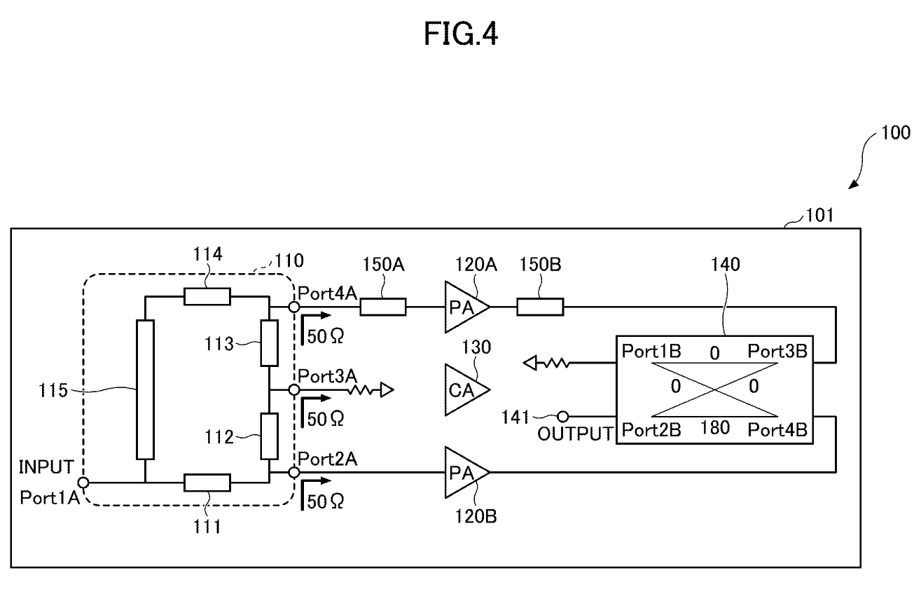

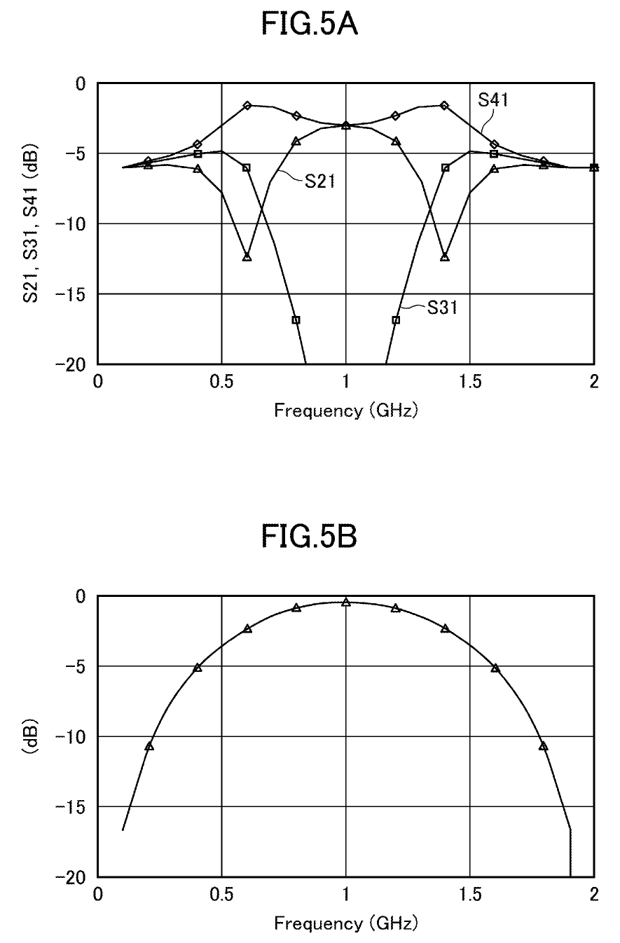

FIG. 4 is a diagram illustrating an example of the operating state of the amplifier 100 at the maximum power. FIG. 5A is a diagram illustrating an example of an S21 parameter of power passing from the port 1A to the port 2A, the S31 parameter of power passing from the port 1A to the port 3A, and an S41 parameter of power passing from the port 1A to the port 4A of the rat-race coupler 110 in the operating state of the amplifier 100 at the maximum power. FIG. 5B is a diagram illustrating an example of S parameters of power passing from the ports 3B and 4B to the port 2B of the 180-degree hybrid circuit 140 in the operating state of the amplifier 100 at the average power.

### Operating State of Amplifier 100 at Average Power (FIG. 2)

When the power level of the input signal input to the port 1A of the amplifier 100 is average power, the PAs 120A and 120B turn off without performing class C amplification.

The PA 120B has large electrostatic capacitance. In this case, when the PA 120B is in an off state, the PA 120B is equivalent to a short circuit as seen from the port 2A. Thus, as illustrated in FIG. 2, the port 2A is short-circuited. When the PA 120B is turned off, a connection point between the PA 120B and the port 4B of the 180-degree hybrid circuit is equivalent to an open circuit, as illustrated in FIG. 2. In this arrangement, the port 4B is open-circuited.

The PA 120A has large capacitance, like the PA 120B, and in an off state, a connection point between the transmission line 150A and the input terminal of the PA 120A is equivalent to a short circuit. The transmission line 150A has a length of a quarter wavelength, and a connection point between the port 4A and the transmission line 150A is equivalent to an open state as illustrated in FIG. 2. As a result, the port 4A is open-circuited.

Further, when the PA 120A is in an off state, a connection point between the output terminal of the PA 120A and the transmission line 150B is equivalent to an open circuit. The transmission line 150B has a length of a quarter wavelength, a connection point between the transmission line 150B and the port 3B of the 180-degree hybrid circuit 140 is equivalent to a short circuit, as illustrated in FIG. 2. As a result, the port 3B is short-circuited.

As described above, when the power level of the input signal input to the port 1A of the amplifier 100 is average power, the PAs 120A and 120B are equivalent to states in which the PAs are disconnected from the ports 4A and 2A of the rat-race coupler 110, respectively. In this arrangement, the input signal input to the port 1A of the rat-race coupler 110 is transmitted only to the port 3A, and the CA 130 performs AB class amplification.

When the signal is output from the output terminal of the CA 130 to the port 1B of the 180-degree hybrid circuit, the signal is transmitted from the port 1B to the ports 3B and 4B with a phase shift of 0 degrees. At the port 3B that is short-circuited, the signal phase is inverted and then the signal with a phase shift of 180 degrees is transmitted to the ports 1B and 2B. At the port 4B that is open-circuited, the signal with a phase shift of 0 degrees is transmitted to the port 1B without changing the signal phase, and the signal with a phase shift of 180 degrees is transmitted to the port 2B.

As a result, the signal that is returned from the port 3B to the port 1B, and the signal that is returned from the port 4B to the port 1B cancel each other because these two signals have a 180-degree phase difference. In addition, the signal that is transmitted from the port 3B to the port 2B, and the signal that is transmitted from the port 4B to the port 2B have an equal phase shift of 180 degrees, and thus these two signals reinforce each other and are output to the output terminal 141.

In this arrangement, when the power level of the input signal input to the port 1A of the amplifier 100 is average power, the input signal input to the port 1A of the rat-race coupler 110 is transmitted only to the port 3A, amplified by the CA 130, then transmitted between the ports 1B and 2B of the 180-degree hybrid circuit, and output from the output terminal 141.

In this case, the PAs 120A and 120B are equivalent to states in which these PAs are disconnected from the ports 4A and 2A of the rat-race coupler 110, respectively, and as a result, reductions in power added efficiency are suppressed.

FIGS. 3A and 3B illustrate simulation results calculated by setting the frequency of the input signal to 1 GHz and setting the lengths of the transmission lines 111 to 115 and the transmission lines 150A and 150B for 1 GHz.

As illustrated in FIG. 3A, the S31 parameter of the power passing from the port 1A to the port 3A of the rat-race coupler 110 is approximately 0 dB at 1 GHz when the amplifier 100 is operating at average power. This indicates that all input signals input to the port 1A of the rat-race coupler 110 are transmitted to the port 3A and not transmitted to the ports 2A and 4A.

As illustrated in FIG. 3B, the S21 parameter of the power passing from the port 1B to the port 2B of the 180-degree hybrid circuit 140 is approximately 0 dB at 1 GHz, indicating that all signals input to the port 1B are output from the port 2B.

As described above, from the simulation results of FIG. 3A, it has been confirmed that, when the amplifier 100 is operating at average power, the PAs 120A and 120B are equivalent to states in which these PAs are disconnected from the ports 4A and 2A of the rat-race coupler 110, respectively, and that all input signals input to the port 1A are transmitted to the port 3A.

From the simulation results of FIG. 3B, it has been confirmed that all signals input to the port 1B of the 180-degree hybrid circuit 140 are output from the port 2B when the amplifier 100 is operating at average power.

### Operating State of Amplifier 100 at Maximum Power (FIG. 4)

In the operating state of the amplifier 100 at maximum power, the PA 120A and the PA 120B perform class C amplification. As a result, the transmission line 150A between the port 4A and the PA 120A has a characteristic impedance of 50 Ω, and the transmission line between the port 2A and the PA 120B has a characteristic impedance of 50 Ω.

In this state, the rat-race coupler 110 does not output a signal from the port 3A. As a result, the port 3A is in a state equivalent to being terminated by a 50 Ω resistor. In this state, no input signal is input, and thus the CA 130 does not perform amplification.

In this state, the PAs 120A and 120B perform class C amplification, and as a result, signals amplified by the PAs 120A and 120B are input to the ports 3B and 4B of the 180-degree hybrid circuit 140, respectively.

When the phase of the input signal input to the port 1A is set to 0 degrees, the phase of the input signal output from the port 4A is 270 degrees. This is because transmission lines 111, 112, and 113, which have a length of a quarter wavelength, each delay the phase by 90 degrees.

In addition, the phase of the input signal output from the transmission line 150A becomes 0 degrees (360 degrees) by being delayed by 90 degrees in the transmission line 150A. The phase of the signal output from the PA 120A is 0 degrees, and the phase of the signal output from the transmission line 150B becomes 90 degrees by being delayed by 90 degrees in the transmission line 150B. Thus, the signal with a phase shift of 90 degrees is input to the port 3B of the 180-degree hybrid circuit 140.

When the phase of the input signal input to the port 1A is set to 0 degrees, the phase of the input signal output from the port 2A is 90 degrees. The input signal with a phase shift of 90 degrees is input to the PA 120B, and the phase is inverted by the PA 120B, so that the phase shift of the signal output from the PA 120B is 270 degrees. As a result, the signal with a phase shift of 270 degrees is input to the port 4B of the 180-degree hybrid circuit 140.

In this arrangement, the signal with a phase shift of 90 degrees is input to the port 3B of the 180-degree hybrid circuit 140, and the signal with a phase shift of 270 degrees is input to the port 4B. The port 1B that is coupled to the output terminal of the CA 130 is in a state equivalent to being terminated by a 50 Ω resistor.

In the 180-degree hybrid circuit 140, the signal with a phase shift of 90 degrees is transmitted from the port 3B to the ports 1B and 2B. Also, the signal with a phase shift of 270 degrees is transmitted from the port 4B to the port 1B, and further, the phase of the signal with a phase shift of 270 degrees changes by 180 degrees and then the signal with a phase shift of 90 degrees is transmitted from the port 4B to the port 2B.

As a result, the respective signals transmitted from the ports 3B and 4B to the port 1B cancel each other, because the signals have a phase difference of 180 degrees. In addition, signals transmitted from the ports 3B and 4B to the port 2B have an equal phase shift of 90 degrees, and thus these signals reinforce each other and are output to the output terminal 141.

In this arrangement, when the power level of the input signal input to the port 1A of the amplifier 100 is maximum power, the input signal input to the port 1A of the rat-race coupler 110 is transmitted only to the ports 4A and 2A, amplified by the PAs 120A and 120B, then transmitted between the ports 3B and 4B and the port 2B of the 180-degree hybrid circuit, and output from the output terminal 141.

In this case, the CA 130 is equivalent to a state in which the CA is disconnected from the port 3A of the rat-race coupler 110, and thus reductions in power added efficiency are suppressed.

FIGS. 5A and 5B illustrate simulation results obtained by setting the frequency of the input signal to 1 GHz and setting the lengths of the transmission lines 111 to 115 and the transmission lines 150A and 150B for 1 GHz.

As illustrated in FIG. 5A, when the amplifier 100 is operating at maximum power, each of the S41 parameter of power passing from the port 1A to the port 4A of the rat-race coupler 110 and the S21 parameter of power passing from the port 1A to the port 2A of the rat-race coupler 110 is approximately -3 dB at 1 GHz. The S31 parameter of power passing from the port 1A to the port 3A of the rat-race coupler 110 is less than -20 dB at 1 GHz.

This indicates that the input signal input to the port 1A of the rat-race coupler 110 is equally divided and transmitted to the ports 4A and 2A, but not to the port 3A.

As illustrated in FIG. 5B, the S parameter of power passing from the ports 3B and 4B to the port 2B of the 180-degree hybrid circuit 140 is approximately 0 dB at 1 GHz, indicating that all signals input to the ports 3B and 4B are output from the port 2B.

As described above, from the simulation results of FIG. 5A, it has been confirmed that, when the amplifier 100 is operating at maximum power, the CA 130 is equivalent to being in a state disconnected from the port 3A of the rat-race coupler 110, and that the input signal input to the port 1A is equally divided and transmitted to the ports 4A and 2B.

Further, from the simulation results of FIG. 5B, it has been confirmed that, when the amplifier 100 is operating at maximum power, all signals input to the ports 3B and 4B of the 180-degree hybrid circuit 140 are output from the port 2B.

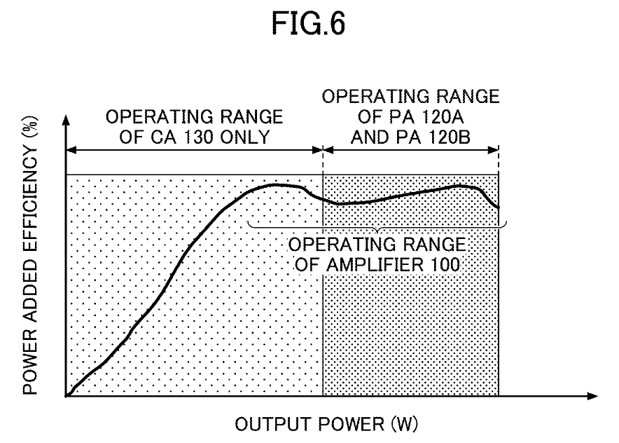

FIG. 6 is a diagram illustrating an example of the relationship between output power (W) and power added efficiency (%) in the amplifier 100. In FIG. 6, the horizontal axis represents the output power (W) of the signal output from the output terminal 141 of the amplifier 100, and the vertical axis represents the power added efficiency (%). The characteristics illustrated in FIG. 6 are simulation results.

On the horizontal axis, the range in which only the CA 130 operates indicates a range in which the PAs 120A and 120B are disconnected from the rat-race coupler 110, and indicates that a signal is transmitted from the rat-race coupler 110 to only the CA 130. Also, the range in which the PAs 120A and 120B operate indicates a range in which the CA 130 is disconnected from the rat-race coupler 110, and indicates that a signal is equally divided and transmitted from the rat-race coupler 110 to the PAs 120A and 120B.

An operating range of the amplifier 100 indicates both the range in which the amplifier 100 operates at average power of the amplifier 100, and the range in which the amplifier 100 operates at maximum power. Although a value of power added efficiency (%) on the vertical axis is not illustrated in FIG. 6, the power added efficiency (%) in the operating range of the amplifier 100 is, as an example, about 30% to 40%, and a value of 40% or more may be obtained. The value of the power added efficiency (%) depends on the configuration of the amplifier 100.

### Effects

An amplifier 100 includes a rat-race coupler 110 having a port 1A, a port 2A, a port 3A, and a port 4A to which an input signal is to be input. A plurality of transmission lines 111, 112, and 113 each having a quarter-wavelength length at a frequency of an input signal are respectively coupled between the port 1A and the port 2A, between the port 2A and the port 3A, and between the port 3A and the port 4A. Transmission lines 114 and 115 each having a three-quarter wavelength length at the frequency of the input signal are coupled between the port 1A and the port 4A. The amplifier 100 includes a PA 120 coupled to the port 4A and configured to perform class C amplification, a PA 120B coupled to the port 2A and configured to perform class C amplification with a phase inverted relative to the PA 120A, and a CA 130 coupled to the port 3A and configured to perform class AB amplification. The amplifier 100 includes a 180-degree hybrid circuit 140 including a port 1B coupled to an output terminal of the CA 130, a port 2B, a port 3B coupled to an output terminal of the PA 120A, and a port 4B coupled to an output terminal of the PA 120B. The 180-degree hybrid circuit 140 inverts a phase of either a signal transmitted from the port 3B to the port 2B or a signal transmitted from the port 4B to the port 2B, and outputs signals from the port 2B in phase with each other. The amplifier 100 includes a first transmission line having a quarter-wavelength length and coupled between the port 4A and the PA 120A, and a second transmission line having the quarter-wavelength length coupled between the PA 120A and the port 3B. In this arrangement, when a power level of the input signal is at a first level that is a predetermined percentage of saturation power of the PAs 120A and 120B, the CA 130 can perform class AB amplification in a state equivalent to being in a state in which the PAs 120A and 120B are disconnected from the rat-race coupler 110. When the power level of the input signal is at a saturation power level of the PAs 120A and 120B, the PAs 120A and 120B can perform class C amplification in a state equivalent to being in a state in which the CA 130 is disconnected from the rat-race coupler 110. As a result, reductions in power added efficiency can be suppressed.

Therefore, the amplifier 100 capable of suppressing reductions in power added efficiency can be provided.

When a power level of the input signal is at a first level that is a predetermined percentage of saturation power of the PA 120A and the PA 120B, the port 2A may be short-circuited, the port 4A may be open-circuited, and the CA 130 may perform class AB amplification. That is, when the power level of the input signal is at the first level that is the predetermined percentage of the saturation power of the PAs 120A and 120B, the port 2A is short-circuited and the port 4A is open-circuited, and thus a state equivalent to being in a state in which the PAs 120A and 120B are disconnected from the rat-race coupler 110 can be obtained. In this arrangement, reductions in power added efficiency can be suppressed.

When a power level of the input signal is at a saturation power level of the PA 120A and the PA 120B, power may be supplied from the port 4A to the PA 120A and from the port 2A to the PA 120B, without supplying power to the port 3A, such that the PA 120A and the PA 120B perform class C amplification. That is, when the power level of the input signal is at the saturation power level of the PA 120A and the PA 120B, power is not supplied to the port 3A, and as a result, a state equivalent to being in a state in which the CA 130 is disconnected from the rat-race coupler 110 is obtained. Therefore, reductions in the power added efficiency can be suppressed.

Although the embodiments are numbered with, for example, “first,” “second,” “third,” or “forth,” the ordinal numbers do not imply priorities of the embodiments. Many other variations and modifications will be apparent to those skilled in the art.

All examples and conditional language recited herein are intended for pedagogical purposes to aid the reader in understanding the invention and the concepts contributed by the inventor to furthering the art, and are to be construed as being without limitation to such specifically recited examples and conditions, nor does the organization of such examples in the specification relate to a showing of the superiority and inferiority of the invention. Although the embodiments of the present invention have been described in detail, it should be understood that the various changes, substitutions, and alterations could be made hereto without departing from the spirit and scope of the invention.

What is claimed is:

1. An amplifier comprising:
a rat-race coupler including:
a first port, a second port, a third port, and a fourth port to which an input signal is to be input, and
a plurality of quarter-wavelength transmission lines at a frequency of the input signal, the plurality of quarter-wavelength transmission lines being respectively coupled between the first port and the second port, between the second port and the third port, and between the third port and the fourth port, and
a three-quarter wavelength transmission line at the frequency of the input signal, the three-quarter wavelength transmission line being coupled between the first port and the fourth port;
a first peak amplifier coupled to the fourth port and configured to perform class C amplification;
a second peak amplifier coupled to the second port and configured to perform class C amplification with a phase inverted relative to the first peak amplifier;
a carrier amplifier coupled to the third port and configured to perform AB class amplification;
a 180-degree hybrid circuit including:
a first terminal coupled to an output terminal of the carrier amplifier,
a second terminal,
a third terminal coupled to an output terminal of the first peak amplifier, and
a fourth terminal coupled to an output terminal of the second peak amplifier, the 180-degree hybrid circuit being configured to invert a phase of either a signal transmitted from the third terminal to the second terminal or a signal transmitted from the fourth terminal to the second terminal, and output signals from the second terminal in phase with each other;
a first transmission line having a quarter wavelength length and coupled between the fourth port and the first peak amplifier; and
a second transmission line having the quarter wavelength length coupled between the first peak amplifier and the third terminal of the carrier amplifier.

2. The amplifier according to claim 1, wherein, when a power level of the input signal is at a first level that is a predetermined percentage of saturation power of the first peak amplifier and the second peak amplifier, the second port is configured to be short-circuited, the fourth port is configured to be open-circuited, and the carrier amplifier is configured to perform the class AB amplification.

3. The amplifier according to claim 1, wherein, when a power level of the input signal is at a saturation power level of the first peak amplifier and the second peak amplifier, power is to be supplied from the fourth port to the first peak amplifier and from the second port to the second peak amplifier, without supplying power to the third port, such that the first peak amplifier and the second peak amplifier perform the class C amplification.
